(19) United States
(12) Patent Application Publication
(10) Pub. No.: US 2010/0038630 A1
(43) Pub. Date: Feb. 18, 2010

(54) Semiconducting siloxane compositions for thin film transistor devices,and making and using the same

(76) Inventors: Tobin J. Marks, Evanston, IL (US); Antonio Facchetti, Chicago, IL (US); He Yan, Skokie, IL (US)

Correspondence Address: K&L Gates LLP, STATE STREET FINANCIAL CENTER, One Lincoln Street, BOSTON, MA, 02111-2950, US

(21) Appl. No.: 11/975,911

(22) Filed: Oct. 22, 2007

Related U.S. Application Data
(60) Provisional application No. 60/853,247, filed on Oct. 20, 2006.

(51) Int. Cl. H01L 51/10; H01L 51/40

(52) U.S. Cl. 257/40; 438/99; 257/E51.007

(57) ABSTRACT

Semiconducting siloxane compositions and methods for manufacturing and use thereof in preparing organic thin-film transistors (OTFTs) are described. The semiconducting siloxane compositions can be crosslinked products of polymeric/monomeric compositions that include silane-derivatized crosslinkable organic p-type compounds and p-type semiconducting polymers.

### CROSS REFERENCE TO RELATED APPLICATION

This application claims priority to and the benefit of U.S. Provisional Patent Application Ser. No. 60/853,247, filed on Oct. 20, 2006, the disclosure of which is incorporated by reference in its entirety.

### STATEMENT REGARDING FEDERALLY SPONSORED RESEARCH OR DEVELOPMENT

The United States government has certain rights to the invention(s) pursuant to Grant Nos. N00014-02-1-0909, DMR0076097, and NCC 2-1363 from the Office of Naval Research, the National Science Foundation, and the National Aeronautics and Space Administration, respectively, all to Northwestern University.

### BACKGROUND

During the past decade, organic field-effect transistors (OFETs), which are organic thin-film transistors (OTFTs), have attracted intense industrial and academic research activity due to their potential application in low-cost, large-area flexible displays and low-end electronics. Developments in this field have been reviewed by Bao, Dimitrakopoulos, and Yoon. See, e.g., Z. N. Bao, et al., J. Mater. Chem. 9:1895, 1999; C. D. Dimitrakopoulos and P. R. L. Malenfant, Adv. Mater. (Weinheim, Ger.) 14:99, 2002; and M. H. Yoon, et al., J. Am. Chem. Soc. 127:1348, 2005. General background information relating to the construction of OFETs can be found, for example, in U.S. Pat. No. 6,864,504.

OFETs can be distinguished from inorganic field effect transistors in that the organic semiconductors in the OFETs can be cheaper and lighter, and can be processed at lower temperatures. These low-temperature processes can save energy, can be compatible with flexible substrates, and can be used for replacing the more energy-intensive and less-convenient processes for preparing inorganic field-effect transistors. The later process can take place at 360° C.

OFETs can be constructed in a variety of ways, including by screen printing, by inkjet printing, by microcontact printing, by spin coating, and by various other processing methods. In general, OFETs can be made by sequentially depositing the appropriate layers of materials onto substrates in patterns that can give functionality to the devices. For examples, an OFET can have a “staggered” geometry, a “coplanar” geometry, or a “top-gate” geometry, as illustrated in FIGS. 1a, 1b, and 1c, respectively. Further, based on the location of source and drain electrodes, OFETs can have a “top-contact” structure, with source and drain electrodes at the top and as the last deposited layer, or a “bottom-contact” structure, with source and drain electrodes at the bottom and as the first deposited layer.

Conventional OFETs utilize silicon substrates as the bottom gate and patterned gold as the top-contact source and drain electrodes. This configuration often cannot be used in solution-based fabrications because organic semiconductors are frequently sensitive to the solvents and chemicals used in the photolithographic patterning or printing of top source and drain electrodes. As a result, configurations that have the source and drain electrodes under the semiconductor layer, as in the coplanar or top-gate geometry, can be used in the solution-based fabrication. Although the top-gate geometry is more desirable for low-cost large-area OFETs with flexible substrates, it is more difficult to fabricate because good contact between the semiconductor layer and the source and drain electrodes can be difficult to maintain in the subsequent processing steps. Further, keeping the semiconductor layer in place while the dielectric and gate material layers are deposited can be problematic.

Additional considerations in OFET fabrication can include mechanical stability and solvent resistance of organic semiconductors, electrical contact of organic semiconductors with metallic electrodes, and interfacial characteristics of organic semiconductors with other materials (e.g., gate substrates). For example, the quality of electrical contact between an organic semiconductor with a gate substrate, a source contact, and/or a drain contact can significantly affect the gate, source, and/or drain threshold voltages of the OFET.

Accordingly, the art desires improvements in organic semiconductor compositions and components for use in OFETs.

### SUMMARY

It has now been discovered that electronic devices such as OTFTs can include hole transporting (“p-type”) semiconducting compositions addressing various deficiencies and shortcomings of the prior art including those outlined above. The present teachings relate to semiconducting compositions as well as related polymeric/monomeric compositions, and methods for preparing and using the same.

In one aspect, the present teachings provide electronic devices that can include p-type semiconducting compositions. Examples of electronic devices include organic field effect-transistors (OFETs) and capacitors.

In some embodiments, the p-type semiconducting compositions can include crosslinked products of polymeric/monomeric compositions. In some embodiments, the semiconducting compositions can be made by reacting or crosslinking the polymeric/monomeric compositions to form a semiconducting matrix or network of polymeric semiconducting compounds.

In some embodiments, the polymeric/monomeric compositions can include p-type semiconducting crosslinkers and p-type semiconducting polymers. For example, the p-type semiconducting crosslinkers can include compounds of Formula I or Formula II:

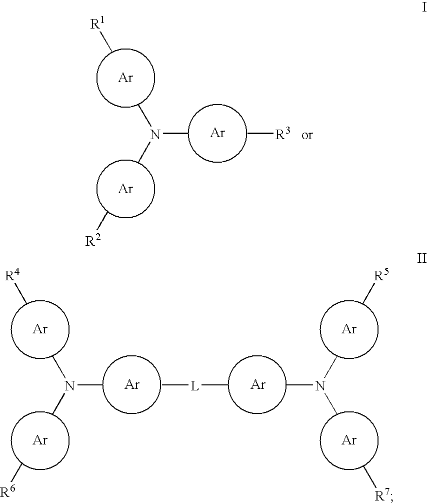

wherein Ar, R¹, R², R³, R⁴, R⁵, R⁶, R⁷, and L are as defined herein.

The foregoing as well as other features and advantages of the present teachings will be more fully understood from the following figures, description, and claims.

### BRIEF DESCRIPTION OF THE DRAWINGS

It should be understood that the drawings described below are for illustration purposes only and are not necessarily to scale. The drawings are not intended to limit the scope of the present teachings in any way.

FIG. 1a is a schematic representation of an OFET that has a “top-contact” or “staggered” structure.

FIG. 1b is a schematic representation of an OFET that has a “bottom-contact” or “coplanar” structure.

FIG. 1c is a schematic representation of an OFET that has a “top-gate” structure.

FIG. 2a shows the transfer plots of some embodiments of TFB and TFB/TPDSi₂ based OFETs of the present teachings.

FIG. 2b shows the response characteristics of some embodiments of TFB/TPDSi₂ based OFETs of the present teachings.

FIG. 2c shows the output plots of some embodiments of coplanar TFB/TPDSi₂ based OFETs of the present teachings.

FIG. 2d shows the output plots of some embodiments of coplanar TFB based OFETs of the present teachings.

FIG. 3a shows the response characteristics of some embodiments of top-gate spincoated TPDSi₂/TFB-blend OFETs of the present teachings. The inset shows the output plot of this device.

FIG. 3b shows the response characteristics of TPDSi₂-only OFETs with staggered or coplanar structure.

### DETAILED DESCRIPTION

Throughout the description, where compositions are described as having, including, or comprising specific components, or where processes are described as having, including, or comprising specific process steps, it is contemplated that compositions of the present teachings also consist essentially of, or consist of, the recited components, and that the processes of the present teachings also consist essentially of, or consist of, the recited process steps.

In the application, where an element or component is said to be included in and/or selected from a list of recited elements or components, it should be understood that the element or component can be any one of the recited elements or components and can be selected from a group consisting of two or more of the recited elements or components. Further, it should be understood that elements and/or features of a composition, an apparatus, or a method described herein can be combined in a variety of ways without departing from the spirit and scope of the present teachings, whether explicit or implicit herein.

The use of the terms “include,” “includes,” “including,” “have,” “has,” or “having” should be generally understood as open-ended and non-limiting unless specifically stated otherwise.

The use of the singular herein includes the plural (and vice versa) unless specifically stated otherwise. In addition, where the use of the term “about” is before a quantitative value, the present teachings also include the specific quantitative value itself, unless specifically stated otherwise. As used herein, the term “about” refers to a ±10% variation from the nominal value.

It should be understood that the order of steps or order for performing certain actions is immaterial so long as the present teachings remain operable. Moreover, two or more steps or actions may be conducted simultaneously.

As used herein, “polymer” or “polymeric compound” refers to a molecule including at least two or more repeating units connected by covalent chemical bonds. The polymer or polymeric compound can have only one type of repeating unit as well as two or more types of different repeating units. In the latter case, the term “copolymer” or “copolymeric compound” can be used herein instead, especially when the polymer includes chemically significantly different repeating units. Unless specified otherwise, the assembly of the repeating units in the copolymer can be head-to-tail, head-to-head, or tail-to-tail. In addition, unless specified otherwise, the copolymer can be a random copolymer, an alternating copolymer, or a block copolymer. The polymer can include one or more pendant groups. As used herein, a “pendant group” refers to a moiety that is substituted on the backbone of a polymer.

As used herein, “solution-processable” refers to compounds, materials, or compositions that can be used in various solution-phase processes including spin-coating, printing (e.g., inkjet printing), spray coating, electrospray coating, drop casting, dip coating, and blade coating.

As used herein, “halo” or “halogen” refers to fluoro, chloro, bromo, and iodo.

As used herein, “alkoxy” refers to —O-alkyl group. An alkoxy group can have 1 to 20 carbon atoms, for example 1 to 10 carbon atoms (i.e., C₁₋₁₀ alkoxy group). Examples of alkoxy groups include, but are not limited to, methoxy, ethoxy, propoxy (e.g., n-propoxy and isopropoxy), t-butoxy groups, and the like.

As used herein, “alkyl” refers to a straight-chain or branched saturated hydrocarbon group. Examples of alkyl groups include methyl (Me), ethyl (Et), propyl (e.g., n-propyl and isopropyl), butyl (e.g., n-butyl, isobutyl, s-butyl, t-butyl), pentyl groups (e.g., n-pentyl, isopentyl, neopentyl), and the like. An alkyl group can have 1 to 20 carbon atoms, for example 1 to 10 carbon atoms (i.e., C₁₋₁₀ alkyl group). A lower alkyl group typically has up to 4 carbon atoms. Examples of lower alkyl groups include methyl, ethyl, propyl (e.g., n-propyl and isopropyl), and butyl groups (e.g., n-butyl, isobutyl, s-butyl, t-butyl).

As used herein, “haloalkyl” refers to an alkyl group having one or more halogen substituents. A haloalkyl group can have 1 to 20 carbon atoms, for example 1 to 10 carbon atoms (i.e., C₁₋₁₀ haloalkyl group). Examples of haloalkyl groups include CF₃, C₂F₅, CHF₂, CH₂F, CCl₃, CHCl₂, CH₂Cl, C₂Cl₅, and the like. Perhaloalkyl groups, i.e., alkyl groups wherein all of the hydrogen atoms are replaced with halogen atoms (e.g., CF₃ and C₂F₅), are included within the definition of “haloalkyl.” For example, a C₁₋₁₀ haloalkyl group can have the formula —CₐX₂ₐ₊₁— or —CₐH_{2a+1-b}—, wherein X is F, Cl, Br, or I, a is an integer in the range of 1 to 10, and b is an integer in the range of 0 to 20, provided that b is not greater than 2a+1.

As used herein, “alkenyl” refers to a straight-chain or branched alkyl group having one or more carbon-carbon double bonds. An alkenyl group can have 1 to 20 carbon atoms, for example 1 to 10 carbon atoms (i.e., C₁₋₁₀ alkenyl group). Examples of alkenyl groups include, but are not limited to, ethenyl, propenyl, butenyl, pentenyl, hexenyl, butadienyl, pentadienyl, hexadienyl groups, and the like. The one or more carbon-carbon double bonds can be internal (such as in 2-butene) or terminal (such as in 1-butene).

As used herein, “cycloalkyl” refers to a non-aromatic carbocyclic group including cyclized alkyl, alkenyl, and alkynyl groups. A cycloalkyl group can have 3 to 20 carbon atoms, for example 3 to 14 carbon atoms (i.e., C₃₋₁₄ cycloalkyl group). A cycloalkyl group can be monocyclic (e.g., cyclohexyl) or polycyclic (e.g., containing fused, bridged, and/or spiro ring systems), wherein the carbon atoms are located inside or outside of the ring system. Any suitable ring position of the cycloalkyl group can be covalently linked to the defined chemical structure. Examples of cycloalkyl groups include, but are not limited to, cyclopropyl, cyclopropylmethyl, cyclobutyl, cyclopentyl, cyclohexyl, cyclohexylmethyl, cyclohexylethyl, cycloheptyl, cyclopentenyl, cyclohexenyl, cyclohexadienyl, cycloheptatrienyl, norbornyl, norpinyl, norcaryl, adamantyl, and spiro[4.5]decanyl groups, as well as their homologs, isomers, and the like. In some embodiments, cycloalkyl groups can be substituted as disclosed herein.

As used herein, “heteroatom” refers to an atom of any element other than carbon or hydrogen and includes, for example, nitrogen, oxygen, sulfur, phosphorus, and selenium.

As used herein, “cycloheteroalkyl” refers to a non-aromatic cycloalkyl group that contains at least one ring heteroatom selected from O, N and S, and optionally contains one or more double or triple bonds. A cycloheteroalkyl group can have 3 to 20 ring atoms, for example 3 to 14 ring atoms (i.e., 3-14 membered cycloheteroalkyl group). One or more N or S atoms in a cycloheteroalkyl ring may be oxidized (e.g., morpholine N-oxide, thiomorpholine S-oxide, thiomorpholine S,S-dioxide). In some embodiments, nitrogen atoms of cycloheteroalkyl groups can bear a substituent, for example, a hydrogen atom, an alkyl group, or other substituents as described herein. Cycloheteroalkyl groups can also contain one or more oxo groups, such as oxopiperidyl, oxooxazolidyl, dioxo-(1H,3H)-pyrimidyl, oxo-2(1H)-pyridyl, and the like. Examples of cycloheteroalkyl groups include, among others, morpholinyl, thiomorpholinyl, pyranyl, imidazolidinyl, imidazolinyl, oxazolidinyl, pyrazolidinyl, pyrazolinyl, pyrrolidinyl, pyrrolinyl, tetrahydrofuranyl, tetrahydrothiophenyl, piperidinyl, piperazinyl, and the like. In some embodiments, cycloheteroalkyl groups can be substituted as disclosed herein.

As used herein, “aryl” refers to an aromatic monocyclic hydrocarbon ring system or a polycyclic ring system in which two or more aromatic hydrocarbon rings are fused (i.e., having a bond in common with) together or at least one aromatic monocyclic hydrocarbon ring is fused to one or more cycloalkyl and/or cycloheteroalkyl rings. An aryl group can have from 6 to 14 carbon atoms in its ring system, which can include multiple fused rings. In some embodiments, a polycyclic aryl group can have from 8 to 14 carbon atoms. Any suitable ring position of the aryl group can be covalently linked to the defined chemical structure. Examples of aryl groups having only aromatic carbocyclic ring(s) include, but are not limited to, phenyl, 1-naphthyl (bicyclic), 2-naphthyl (bicyclic), anthracenyl (tricyclic), phenanthrenyl (tricyclic) and like groups. Examples of polycyclic ring systems in which at least one aromatic carbocyclic ring is fused to one or more cycloalkyl and/or cycloheteroalkyl rings include, among others, benzo derivatives of cyclopentane (i.e., an indanyl group, which is a 5,6-bicyclic cycloalkyl/aromatic ring system), cyclohexane (i.e., a tetrahydronaphthyl group, which is a 6,6-bicyclic cycloalkyl/aromatic ring system), imidazoline (i.e., a benzimidazolinyl group, which is a 5,6-bicyclic cycloheteroalkyl/aromatic ring system), and pyran (i.e., a chromenyl group, which is a 6,6-bicyclic cycloheteroalkyl/aromatic ring system). Other examples of aryl groups include, but are not limited to, benzodioxanyl, benzodioxolyl, chromanyl, indolinyl groups, and the like. In some embodiments, aryl groups can be substituted as disclosed herein.

As used herein, “heteroaryl” refers to an aromatic monocyclic ring system containing at least 1 ring heteroatom selected from oxygen (O), nitrogen (N) and sulfur (S) or a polycyclic ring system where at least one of the rings present in the ring system is aromatic and contains at least 1 ring heteroatom. Polycyclic heteroaryl groups include two or more heteroaryl rings fused together and monocyclic heteroaryl rings fused to one or more aromatic carbocyclic rings, non-aromatic carbocyclic rings, and/or non-aromatic cycloheteroalkyl rings. A heteroaryl group, as a whole, can have, for example, from 5 to 14 ring atoms and contain 1-5 ring heteroatoms. The heteroaryl group can be attached to the defined chemical structure at any heteroatom or carbon atom that results in a stable structure. Generally, heteroaryl rings do not contain O—O, S—S, or S—O bonds. However, one or more N or S atoms in a heteroaryl group can be oxidized (e.g., pyridine N-oxide, thiophene S-oxide, thiophene S,S-dioxide). Examples of heteroaryl groups include, for example, the 5-membered monocyclic and 5-6 bicyclic ring systems shown below:

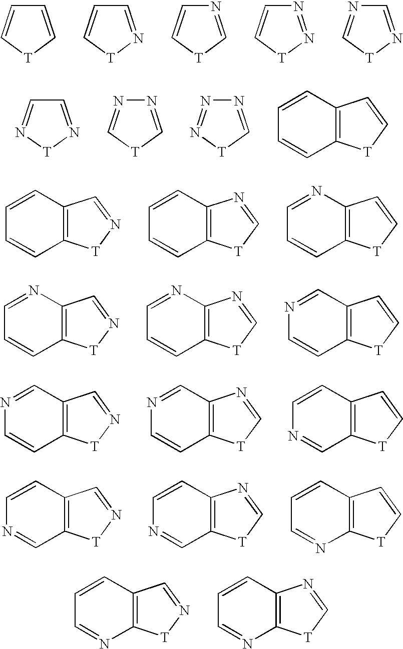

where T is O, S, NH, N-alkyl, N-aryl, or N-(arylalkyl) (e.g., N-benzyl). Examples of heteroaryl groups include pyrrolyl, furyl, thienyl, pyridyl, pyrimidyl, pyridazinyl, pyrazinyl, triazolyl, tetrazolyl, pyrazolyl, imidazolyl, isothiazolyl, thiazolyl, thiadiazolyl, isoxazolyl, oxazolyl, oxadiazolyl, indolyl, isoindolyl, benzofuryl, benzothienyl, quinolyl, 2-methylquinolyl, isoquinolyl, quinoxalyl, quinazolyl, benzotriazolyl, benzimidazolyl, benzothiazolyl, benzisothiazolyl, benzisoxazolyl, benzoxadiazolyl, benzoxazolyl, cinnolinyl, 1H-indazolyl, 2H-indazolyl, indolizinyl, isobenzofuyl, naphthyridinyl, phthalazinyl, pteridinyl, purinyl, oxazolopyridinyl, thiazolopyridinyl, imidazopyridinyl, furopyridinyl, thienopyridinyl, pyridopyrimidinyl, pyridopyrazinyl, pyridopyridazinyl, thienothiazolyl, thienoxazolyl, thienoimidazolyl, and the like. Further examples of heteroaryl groups include, but are not limited to, 4,5,6,7-tetrahydroindolyl, tetrahydroquinolyl, benzothienopyridyl, benzofuropyridyl, and the like. In some embodiments, heteroaryl groups can be substituted as disclosed herein.

At various places in the present specification, substituents of compounds are disclosed in groups or in ranges. It is specifically intended that the description include each and every individual subcombination of the members of such groups and ranges. For example, the term “C₁₋₆ alkyl” is specifically intended to individually disclose C₁, C₂, C₃, C₄, C₅, C₆, C₁-C₆, C₁-C₅, C₁-C₄, C₁-C₃, C₁-C₂, C₂-C₆, C₂-C₅, C₂-C₄, C₂-C₃, C₃-C₆, C₃-C₅, C₃-C₄, C₄-C₆, C₄-C₅, and C₅-C₆ alkyl. By way of other examples, an integer in the range of 0 to 40 is specifically intended to individually disclose 0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, and 40, and an integer in the range of 1 to 20 is specifically intended to individually disclose 1, 2, 3, 4, 5, 6, 7, 8, 9, 10, 11, 12, 13, 14, 15, 16, 17, 18, 19, and 20. Additional examples include that the phrase “optionally substituted with 1-5 substituents” is specifically intended to individually disclose a chemical group that can include 0, 1, 2, 3, 4, 5, 0-5, 0-4, 0-3, 0-2, 0-1, 1-5, 1-4, 1-3, 1-2, 2-5, 2-4, 2-3, 3-5, 3-4, and 4-5 substituents.

As used herein, a “p-type semiconducting material” or a “p-type semiconductor” refers to a semiconducting material having holes as the majority current carriers. In some embodiments, when a p-type semiconducting material is deposited on a substrate, it can provide a hole mobility in excess of about 10⁻⁵ cm²/Vs. In the case of field-effect devices, a p-type semiconductor can also exhibit a current on/off ratio of greater than about 1000.

As used herein, “field effect mobility” refers to a measure of the velocity with which charge carriers, for example, holes (or units of positive charge) in the case of a p-type semiconducting material, move through the material under the influence of an electric field.

Throughout the specification, structures may or may not be presented with chemical names. Where any question arises as to nomenclature, the structure prevails.

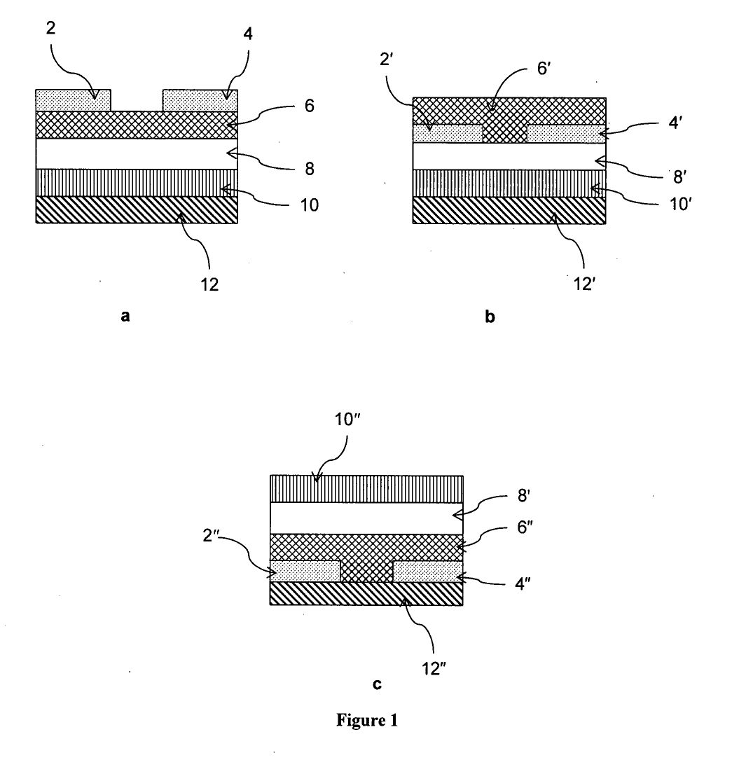

In one aspect, the present teachings provide electronic devices that can include semiconducting compositions (e.g., shown as 6, 6′, and 6″ in FIGS. 1a, 1b, and 1c, respectively) of the present teachings. For example, the electronic devices can be thin film transistors, for example, organic field-effect transistors (OFETs), capacitors, or sensors.

In some embodiments, the electronic devices can further include a gate component (e.g., shown as 10, 10′, and 10″ in FIGS. 1a, 1b, and 1c, respectively). In some embodiments, the electronic devices can further include a substrate (e.g., shown as 12, 12′, and 12″ in FIGS. 1a, 1b, and 1c, respectively). For example, the substrate can be selected from a glass, a silicon, an indium oxide material, and a polymeric material. In other examples, the combination of the gate component and the substrate (i.e., the gate-substrate) can be selected from a doped silicon, an indium tin oxide (ITO), ITO-coated glass, ITO-coated Mylar, aluminum, a doped polythiophene, a conductor on a plastic substrate, and the like.

In some embodiments, the electronic devices can further include a dielectric component (e.g., shown as 8, 8′, and 8″ in FIGS. 1a, 1b, and 1c, respectively). For example, the dielectric component can be independently selected from oxide dielectrics (e.g., silicon oxides) and organic dielectrics (e.g., polymeric dielectrics and molecular dielectrics). In certain embodiments, the dielectric component can include silicon oxides. In certain embodiments, the dielectric component can include a thermally or photochemically curable polymer or a self-assembled nanodielectric.

In some embodiments, the electronic devices can further include one or more metallic contact components, including source contact components and drain components (e.g., shown as 2, 2′, 2″, 4, 4′, and 4″ in FIGS. 1a, 1b, and 1c, respectively). For example, the metallic contact components can be independently made of silver, platinum, palladium, copper, gold, or alloys thereof. In certain embodiments, each of the metallic components can be made of gold. In particular embodiments, the electronic device can include a semiconducting composition, a substrate, a gate component, a dielectric component, and one or more metallic contact components.

In some embodiments, the semiconducting compositions in the electronic devices can include crosslinked polymeric matrices formed by the semiconducting crosslinkers described herein, in which other semiconducting polymers and polymeric chains can be covalently crosslinked by one or more semiconducting crosslinkers, or embedded, entrapped, or otherwise incorporated (e.g., mixed or blended) to form a matrix or network defining the semiconducting composition. In particular embodiments, the semiconducting composition can include a semiconducting polymer as described herein embedded in the crosslinked matrices formed by the semiconducting crosslinkers. In particular embodiments, the semiconducting compositions can exhibit hole transporting properties.

In some embodiments, the semiconducting compositions of the present teachings can be thin, uniform, and pinhole-free, and can afford good long-term stability, good adhesion to various materials (e.g., substrates, drain and source electrodes, and dielectric materials), good solution-processability and fabricability at low temperatures and/or atmospheric pressures, and compatibility with various materials that can be used in fabricating electronic devices. In certain embodiments, the thickness of the semiconducting compositions can be controlled and can be made with a thickness from about 5 nm to several microns. For example, semiconducting films prepared according to the present teachings can have a thickness range from about 5 nm to about 10 μm (e.g., between about 5 nm and about 20 nm). In particular embodiments, the semiconducting films can be relatively thin (e.g., less than about 50 nm) or ultra-thin (e.g., less than about 20 nm or less than about 10 nm). For example, the semiconducting films can have a thickness of about 30 nm or about 40 nm. In other examples, the semiconducting films can have a thickness of about 5 nm or about 10 nm. In certain embodiments, the semiconducting films can exhibit high mechanical flexibility and can have smooth surfaces.

In certain embodiments, the semiconducting compositions can adhere to different materials (e.g., gate substrates, including doped silicon, aluminum, or indium tin oxide, and source and drain contacts, including silver, platinum, palladium, copper, gold, or alloys thereof). In certain embodiments, the semiconducting compositions can be compatible with a wide range of dielectric materials. In certain embodiments, the semiconducting compositions can be insoluble in various solvents. In particular embodiments, the semiconducting compositions can be insoluble in the mother solutions.

In some embodiments, the semiconducting compositions can include crosslinked products of polymeric/monomeric compositions. In certain embodiments, each of the polymeric/monomeric compositions can include one or more p-type semiconducting polymers (i.e., a polymeric component) and one or more p-type semiconducting crosslinkers (i.e., a crosslinker component). In certain embodiments, the polymeric/monomeric compositions can include the polymeric components and the crosslinker components as separate chemical moieties. For example, the crosslinker components can include one or more crosslinkers that can be small molecules having one or more crosslinking groups. In some embodiments, the polymeric/monomeric compositions can further include one or more solvents. In some embodiments, the polymeric/monomeric compositions can enable high-throughput fabrication of the semiconducting compositions.

In some embodiments, the crosslinker components of the polymeric/monomeric compositions can include p-type semiconducting crosslinkers that include two or more silyl groups, for example, two or more hydrolyzable silyl groups. For example, these silyl groups can include one or more (e.g., one, two, or three) hydrolyzable moieties, such as halo groups, amino groups, alkoxy groups, and ester groups, that can react with H₂O or —OH groups and induce crosslinking. In certain embodiments, the crosslinkers can include silane-derivatized, crosslinkable, p-type semiconducting compounds of relatively low molecular weight. In certain embodiments, the p-type semiconducting crosslinkers can include p-type π-conjugated semiconducting compounds.

For example, the p-type semiconducting crosslinkers can have Formula I or Formula II:

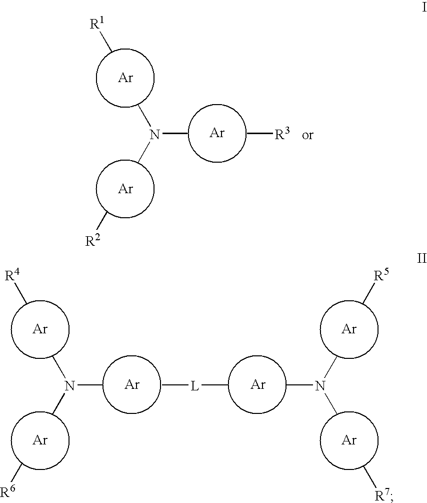

wherein:

R¹, R², R³, R⁵, R⁶, and R⁷ independently are H or a C₁₋₁₀ alkyl group optionally substituted with 1-4 —SiR⁸R⁹R¹⁰;

Ar is a C₆₋₁₄ aryl group or a 5-14 membered heteroaryl group, each of which optionally is substituted with 1-4 R¹¹;

R⁸, R⁹, and R¹⁰ independently are halogen, —N(C₁₋₁₀ alkyl)₂, —C(O)O(C₁₋₁₀ alkyl), a C₁₋₁₀ alkyl group, or a C₁₋₁₀ alkoxy group;

R¹¹, at each occurrence, is halogen, —CN, —NO₂, —C(O)H, —C(O)OH, —CONH₂, —OH, —NH₂, —CO(C₁₋₁₀ alkyl), —C(O)OC₁₋₁₀ alkyl, —CONH(C₁₋₁₀ alkyl), —CON(C₁₋₁₀ alkyl)₂, —OC₁₋₁₀ alkyl, —NH(C₁₋₁₀ alkyl), —N(C₁₋₁₀ alkyl)₂, a C₁₋₁₀ alkyl group, a C₂₋₁₀ alkenyl group, a C₂₋₁₀ alkynyl group, a C₁₋₁₀ haloalkyl group, a C₁₋₁₀ alkoxy group, a C₆₋₁₄ aryl group, a C₃₋₁₄ cycloalkyl group, a 3-14 membered cycloheteroalkyl group, or a 5-14 membered heteroaryl group; and

L is a divalent C₁₋₁₀ alkyl group, a divalent C₆₋₁₄ aryl group, a divalent 5-14 membered heteroaryl group, or a covalent bond.

In some embodiments, at least one of R¹, R², and R³ or at least one of R⁴, R⁵, R⁶, and R⁷ can independently be a C₁₋₁₀ alkyl group substituted with 1-4 —SiR⁸R⁹R¹⁰. In certain embodiments, at least two of R¹, R², and R³ or at least two of R⁴, R⁵, R⁶, and R⁷ can independently be a C₁₋₁₀ alkyl group substituted with 1-4 —SiR⁸R⁹R¹⁰. For example, —SiR⁸R⁹R¹⁰ can be a tri(C₁₋₁₀ alkoxy)silyl group, a trihalosilyl group, a di(C₁₋₁₀ alkoxy)halosilyl group, a di(C₁₋₁₀ alkyl)halosilyl group, a dihalo(C₁₋₁₀ alkyl)silyl group, or a dihalo(C₁₋₁₀ alkoxy)silyl group. In particular embodiments, at least two of R¹, R², and R³ can independently be a C₁₋₄ alkyl group substituted with —SiCl₃ or —Si(C₁₋₁₀ alkoxy)₃. In particular embodiments, at least two of R⁴, R⁵, R⁶, and R⁷ can independently be a C₁₋₄ alkyl group substituted with —SiCl₃ or —Si(C₁₋₁₀ alkoxy)₃.

In some embodiments, Ar can be a C₆₋₁₀ aryl group or a 5-10 membered heteroaryl group, each of which can be optionally substituted with 1-4 R¹¹. For example, the C₆₋₁₀ aryl group or a 5-10 membered heteroaryl group can be selected from a phenyl group, a thienyl group, a furanyl group, a pyrrolyl group, an indenyl group, a naphthyl group, a benzothienyl group, a benzofuranyl group, and an indolyl group. In certain embodiments, Ar can be a phenyl group.

In some embodiments, L can be a divalent C₆₋₁₄ aryl group or a covalent bond. In certain embodiments, L can be a covalent bond.

In some embodiments, the semiconducting crosslinkers of Formula I can include silylated compounds derived from a triphenylamine, such as a diphenyl[4-(3-trichlorosilylpropyl)phenyl]amine, a di[4-(3-trichlorosilylpropyl)phenyl]phenylamine, or a tri[4-(3-trichlorosilylpropyl)phenyl]amine. In some embodiments, the semiconducting crosslinkers of Formula II can include a N4,N4′-diphenyl-N4,N4′-bis(4-((trichlorosilyl)(C₁₋₄ alkyl))phenyl)biphenyl-4,4′-diamine. In particular embodiments, the semiconducting crosslinkers can include N4,N4′-diphenyl-N4,N4′-bis(4-((trichlorosilyl)propyl)phenyl)biphenyl-4,4′-diamine.

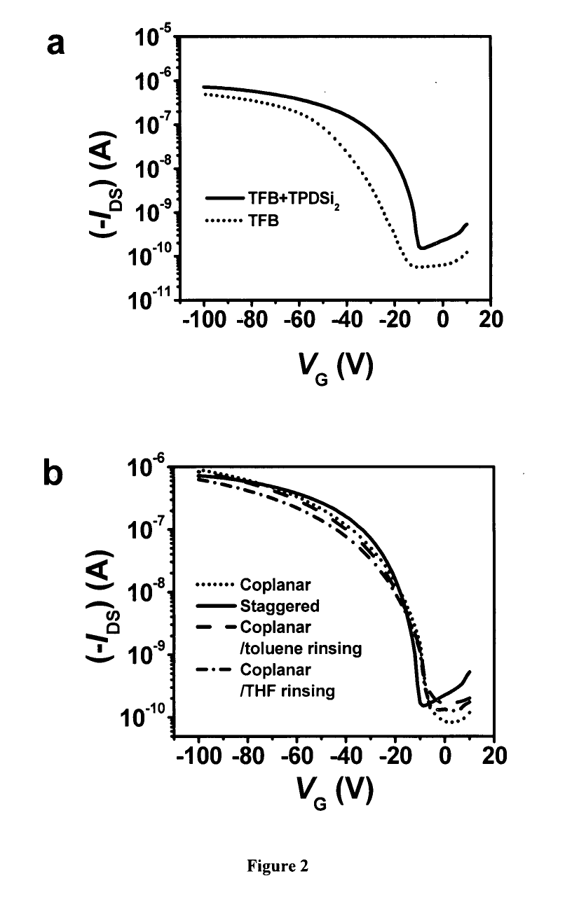

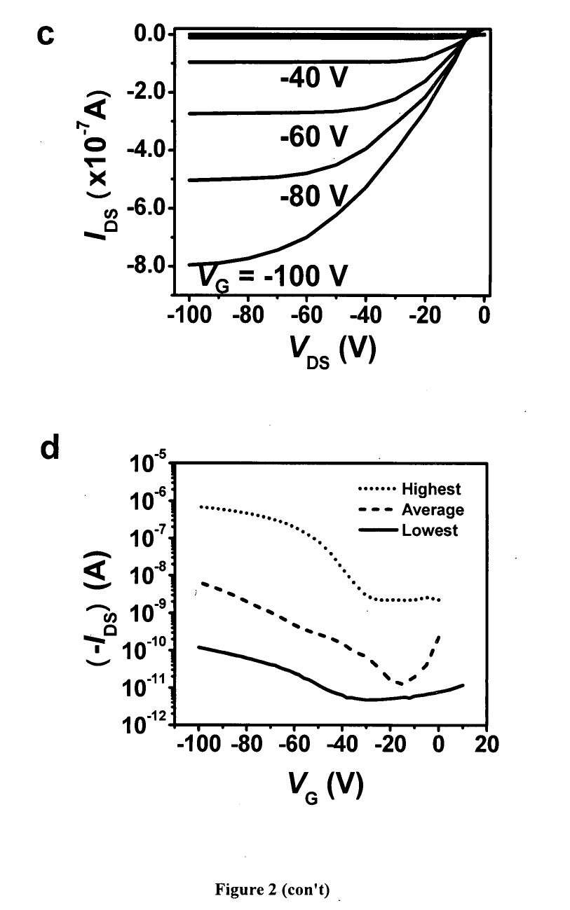

The semiconducting crosslinkers can include p-type compounds described more fully in co-pending U.S. patent application Ser. No. 10/924,730, filed on Aug. 24, 2004, published as U.S. Patent Application Publication No. US 2005/0234256 on Oct. 20, 2005, in particular FIGS. 2A-2G and 11A-11D together with the specification and examples corresponding thereto, and U.S. Pat. No. 5,834,100, issued Nov. 10, 1998, in particular FIGS. 2A-2C together with specification and examples corresponding thereto, each of which is incorporated by reference herein in its entirety.

In some embodiments, the p-type semiconducting polymers in the polymeric/monomeric compositions can include p-type π-conjugated polymers. For example, the p-type semiconducting polymers can include polyfluorenes, polyarylsiloles, polycarbazoles, polyarylamines, polythiophenes, polyhexathiophenes, poly(ethylene dioxide thiophene)s, polyanilines, polypyrroles, polypyrazoles, polyvinylpyridines, polyvinylphenols, polyacetylenes, polydiacetylenes, poly(p-phenylene)s, together with derivatives of such polymers, or other structures having branched or unbranched conjugated hydrocarbon structures, with or without included heteroatoms, or aromatic or heterocyclic groups fused or bonded in a conjugated manner in series and combinations of such polymers and/or derivatives. Without limitation, various other p-type semiconducting polymers, useful in conjunction with this invention, are discussed in U.S. Pat. No. 7,057,205, which is hereby incorporated by reference. In certain embodiments, the p-type semiconducting polymers can include polythiophenes, polyfluorenes, polyarylsiloles, polycarbazoles, and polyarylamines. In particular embodiments, the p-type semiconducting polymers can include poly[9,9-dioctyl-fluorene-co-N-4-butylphenyl)-diphenylamine] (“TFB”).

In some embodiments, the polymeric/monomeric compositions can include anhydrous solvents. For example, at least one of the p-type semiconducting polymers and crosslinkers can be dissolved in an anhydrous solvent. In certain embodiments, at least one of the semiconducting crosslinkers and semiconducting polymers can be highly soluble in an anhydrous solvent. In particular embodiments, the crosslinker component and the polymeric component can be dissolved in the same solvent or in different solvents before combining with each other to provide the polymeric/monomeric compositions. As used herein, a compound can be considered soluble in a solvent when at least 1 mg of the compound is soluble in 1 mL of the solvent. Examples of common solvents include petroleum ethers; acetonitrile; aromatic hydrocarbons such as benzene, toluene, xylene, and mesitylene; ketones such as acetone, cyclopentanone (CP), methyl ethyl ketone, and 2-butanone; ethers such as tetrahydrofuran (THF), dioxane, bis(2-methoxyethyl)ether (diglyme), diethyl ether, di-isopropyl ether, and t-butyl methyl ether; alcohols such as methanol, ethanol, butanol, and isopropyl alcohol; aliphatic hydrocarbons such as hexanes; acetates such as methyl acetate, ethyl acetate (EtOAc), methyl formate, ethyl formate, isopropyl acetate; and halogenated aliphatic and aromatic hydrocarbons such as dichloromethane, chloroform, ethylene chloride, chlorobenzene, dichlorobenzene, and trichlorobenzene.

Without wishing to be bound to any particular theory, crosslinking reactions with these p-type semiconducting crosslinkers rely on fast and quantitative coupling reactions of the trifunctionalized silyl groups (e.g., —SiR⁸R⁹R¹⁰ as described herein) with water and/or the hydroxyl groups of hydroxy-functionalized molecules or polymers to produce siloxane networks.

Accordingly, in some embodiments, the semiconducting compositions can be prepared by crosslinking of the polymeric/monomeric compositions described herein. For example, the crosslinking step can include annealing at an ambient temperature or at an elevated temperature optionally in a high-humidity environment (e.g., ˜70%-90% humidity) for a period of time (e.g., 5 minutes to 3 hours), followed by dry curing (e.g., in a vacuum oven) at a similar temperature range for a longer period of time (e.g., 1-3 hours). In certain embodiments, the ambient temperature can be in a range from about 15° C. to about 35° C., for example, at about 15° C., about 20° C., about 25° C., about 30° C., or about 35° C. In certain embodiments, the elevated temperature can be in a range from about 50° C. to about 150° C., from about 70° C. to about 120° C., or from about 80° C. to about 100° C.

In some embodiments, preparations of the semiconducting compositions can be performed in air. Silane hydrolysis, condensation, and/or crosslinking can occur within seconds after deposition under ambient conditions. In certain embodiments, the preparation can be controlled by using different atmosphere conditions during film deposition or annealing.

In some embodiments, the crosslinking temperatures, typically lower than 130° C., can be compatible with common plastic substrates employed in organic electronics, such as polyethylene terephthalate (PET) or polyethylene naphthalate (PEN). In addition, the crosslinking chemistry according to the present teachings can ensure strong adhesion of the semiconducting compositions to metallic components, for example, a source contact or a drain contact, or substrates, for example, a gate substrate, thus preventing delamination upon successive deposition and/or patterning of subsequent device layers, as well as during device operation.

In another aspect, the present teachings provide methods for making electronic devices. In some embodiments, the methods can include preparation of semiconducting compositions as described herein. In certain embodiments, the methods can include preparation of semiconducting films.

In some embodiments, the methods can include applying polymeric/monomeric compositions of the present teachings onto substrate components, dielectric components, and/or metallic contact components and crosslinking the polymeric/monomeric compositions. In certain embodiments, the crosslinking step can be achieved at an ambient temperature, for example, at a range from about 15° C. to about 35° C. In certain embodiments, the crosslinking step can include heating at a temperature within a range from about 80° C. to about 100° C. optionally in a high-humidity atmosphere.

In some embodiments, various film deposition techniques can be used to prepare the semiconducting films. Exemplary techniques can include casting (e.g., drop-casting), dip coating, blade coating, spraying, printing, and spin-coating. In certain embodiments, the spin-coating can be used to prepare the semiconductor films. Spin-coating involves applying an excess amount of a polymeric/monomeric composition (e.g., a solution of a polymeric component and a crosslinker component) onto a surface, then rotating the surface at high speed to spread the fluid by centrifugal force. The thickness and the surface morphology of the resulting semiconducting film can be determined by the spin-coating rate, the concentration of the solution, as well as the solvent used. In certain embodiments, printings can be used to form the semiconducting films. The thickness of the semiconducting film in these cases can be determined by the concentration of the solution, the choice of solvent, and the number of printing repetitions. In particular embodiments, inkjet printing techniques can be used to prepare the semiconducting films. In particular embodiments, contact printing techniques can be used to prepare the semiconducting films. Exemplary contact printing techniques can include screen-printing, gravure, offset, and microcontact printing.

In some embodiments, the methods can include applying the semiconducting compositions of the present teaching to a substrate optionally coated with one or more layers of materials appropriate for the construction of OTFTs. In certain embodiments, the application of the semiconducting compositions can include applying the polymeric/monomeric compositions of the present teachings, for example, by spincoating or other means, and crosslinking the polymeric/monomeric compositions. In particular embodiments, the method can include applying a dielectric component on a gate substrate; applying a semiconducting composition on the dielectric component; and applying a source contact and a drain contact on the semiconducting composition. In particular embodiments, the method can include applying a dielectric component on a gate substrate; applying a source contact and a drain contact on the dielectric component; and applying a semiconducting composition on the dielectric component, the source contact, and the drain contact. In particular embodiments, the method can include applying a source contact and a drain contact on a substrate; applying a semiconducting composition on the substrate, the source contact, and the drain contact; applying a dielectric component on the semiconducting composition; and applying a gate contact on the dielectric component.

Also embraced within the scope of the present teachings are various materials and composites (e.g., structures) that incorporate the semiconducting compositions disclosed herein.

The following examples are provided to illustrate further and to facilitate the understanding of the present teachings and are not in any way intended to be limiting.

### Example 1a

### Preparation of Semiconducting Film

A mixture of 4,4′-bis[p-trichloro-silylpropylphenyl)phenylamino]biphenyl (TPDSi₂) and poly[9,9-dioctyl-fluorene-co-N-(4-butylphenyl)-diphenylamine] (TFB) (1:1 mass ratio, 6 mg/ml) was spin-coated in air at 5000 rpm onto an n⁺-Si/SiO₂ (300 nm) substrate treated with hexamethyldisilazane (HMDS) (or silicon substrates prepatterned with thermally evaporated source and drain electrodes). The crosslinking process occurred during spincoating in air and was completed by curing in the oven at 90° C. for 0.5-1 hour. The resulting films were 30-40 nm thick, and atomic force microscopy micrographs showed that they were extremely smooth with an rms roughness of 1.0-1.5 nm. TPDSi₂ and TFB can be prepared as described, respectively, in H. Yan, et al., Adv. Mater. (Weinheim, Ger.) 15:835, 2003, and in M. H. Yoon, D S. A. DiBenedetto, A. Facchetti, and T. J. Marks, J. Am. Chem. Soc. 127:1348, 2005 and J. S. Kim, P. K. H. Ho, C. E. Murphy, N. Baynes, and R. H. Friend, Adv. Mater. (Weinheim, Ger.) 14:206, 2002. In the present approach, the resulting film included a semiconducting TFB polymer crosslinked with TPDSi₂.

### Example 1b

### Field Effect Mobilities of Semiconducting Layers of OFETs in Staggered Configuration

Comparison of the OFET semiconducting properties of the TPDSi₂+TFB blend semiconductor with that of a TFB-only film in top-contact staggered devices having the following structure: n⁺-Si(gate)/SiO₂-HMDS (300 nm)/semiconductor (30-40 nm)/gold source-drain (50 nm) with channel length L=100 μm and channel width W=5000 μm showed that the field-effect mobilities of the TFB and TFB+TPDSi₂ blend in the staggered structure were ˜8×10⁻⁴ and ˜5×10⁻⁴ cm/V s, respectively, with current Iₒₙ:I_{off} ratios of ˜10⁴. The TFB+TPDSi₂ blend exhibited semiconducting properties comparable to those of TFB alone (Table 1).

TABLE 1
Device performance comparison between TFB-only and TPDSi₂ + TFB
blend-based OFETs having staggered or coplanar Structures.

| Semiconductor | Structure | Mobility (cm²/V s) | V_{T} (V) | Iₒₙ:I_{off} |
|---|---|---|---|---|
| TFB only | Staggered | 8 × 10⁻⁴ | −30 | 10⁵ |
| | Coplanar | 1 × 10⁻⁷-1 × 10⁻³ | −30~−50 | 10²-10³ |
| TFB + TPDSi₂ | Staggered | 5 × 10⁻⁴ | −15 | 10⁴ |
| blend | Coplanar | 1 × 10⁻³ | −8 | 10⁵ |

### Example 1c

### Comparisons of Field Effect Mobilities of Semiconducting Layers of OFETs in Coplanar Configuration

The coplanar devices had the following structure: n⁺-Si(gate)/SiO₂-HMDS (300 nm)/gold source-drain electrodes (50 nm, L=100 μm, W=5000 μm)/semiconductor (30-40 nm). The field effect mobilities of the TPDSi₂+TFB blend in the staggered and coplanar structures were estimated to be ˜5×10⁻⁴ and ˜1×10⁻³ cm²/Vs, respectively, with gate threshold voltages of −15 and −8 V, respectively (Table 1). The best TFB-only coplanar devices exhibited mobilities of ˜1×10⁻³ with gate threshold voltages of ˜−30 V. These results showed that the TPDSi₂+TFB blend had a field-effect mobility comparable to TFB in these device configurations, but equally important, that the TPDSi₂+TFB blend-based coplanar devices exhibited significantly lower gate threshold voltages.

Furthermore, the crosslinked TPDSi₂+TFB blend was insoluble in essentially any organic solvent, and the TPDSi₂+TFB blend-based coplanar devices performed similarly even after device was immersed in toluene or tetrahydrofuran (THF) for 30 seconds [FIG. 2b].

### Example 1d

### Source-Drain Threshold Voltages of OFETs in Coplanar Configuration

From analysis of the output plots of the TPDSi₂+TFB blend-based coplanar OFETs [FIG. 2c], it can be seen that these devices exhibited negligible source-drain threshold voltage, in contrast to TFB-only coplanar devices.

### Example 1e

### Comparisons of Field Effect Mobilities and Source-Drain Threshold Voltages of OFETs in Coplanar Configuration

TFB-only coplanar devices performed erratically, with measured mobilities ranging from ˜1×10⁻⁶ to ˜1×10⁻³ cm²V⁻¹s⁻¹ and threshold voltages from −30 to −50 V [FIG. 2d]. Note also that the high- and low-mobility TFB-only devices exhibited comparable and low Iₒₙ:I_{off} ratios (˜10²), meaning that the enhanced mobility observed in some devices arose not from improved electrode charge injection but most likely from environmental/processing-related doping.

In contrast, the response of the TPDSi₂+TFB blend-based devices was far more uniform and reproducible. TPDSi₂+TFB blend-based coplanar devices were significantly less contact-dominated than the TFB-only devices. Furthermore, the crosslinking process enhanced stability to air doping.

The absence of significant source/drain threshold voltages in TPDSi₂+TFB OFETs can be a consequence of more favorable interfacial contact between the TPDSi₂+TFB blend and the gold electrodes than has been seen for TFB-only devices.

### Example 1f

### Bottom Contact Resistance in OFETs in Coplanar Configuration

The contact resistance in a TPDSi₂+TFB-based coplanar device was measured to be ˜1-10 MΩ-cm using the channel-length dependence contact resistance method, which was less than or comparable to values reported for F8T2[poly(9,9-dioctylfluorene-co-bithiophene)]-based bottom-contact OFETs. See, for example, R. A. Street and A. Salleo, Appl. Phys. Lett. 81:2887, 2002 and L. Burgi, et al., Appl. Phys. Lett. 80:2913, (2002).

### Example 1g

### Gate and Source-Drain Threshold Voltages for OFETs in Top-Gate Configuration

By stepwise spin coating, a top-gate OFET device with the structure:

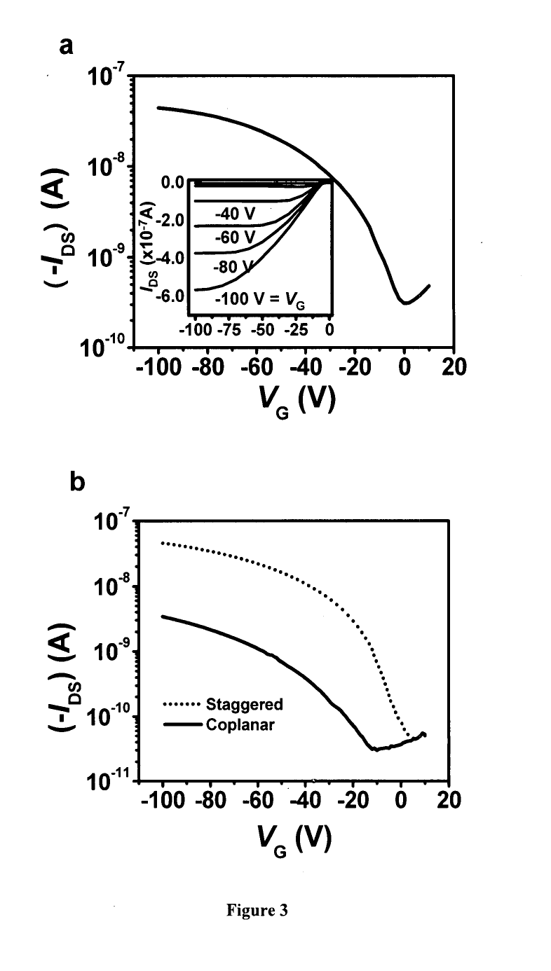

Si/SiO₂ (300 nm) substrate/gold source and drain electrodes (50 nm, L=100 μm, W=5000 μm)/TPDSi₂+TFB (30-50 nm)/polyvinylphenol dielectric (PVP, 900 nm)/gold top gate electrode (50 nm) was fabricated. This top-gate device exhibited negligible gate and source/drain threshold voltages [FIG. 3a]. Typical field effect transistors had gate threshold voltages of less than 10 V.

### Example 2

### Ultrathin Semiconductor Layer OFETs

Staggered and coplanar devices were evaluated using as the semiconductor layer an ultrathin film (5-10 nm thick, rms roughness ˜1.5 nm) of spin-coated TPDSi₂ only. Both types of devices operated properly [FIG. 3b], with the performance of the coplanar configuration better that that of the staggered.

### Example 3

### Self-Assembly of TPDSi₂ on Gold

TPDSi₂ was self-assembled on a clean gold surface using standard siloxane self-assembly procedures as described in H. Yan, et al., Adv. Mater. (Weinheim, Ger.) 15:835, 2003 and J. Cui, et al., Adv. Mater. (Weinheim, Ger.) 14:565, 2002. Infrared reflectance spectroscopy revealed signals on the gold surface at 1470-1625 cm⁻¹.

### Example 4

### Comparison of OFETs Using Composition with and without Crosslinking Agent

Either a protic (methanol) or aprotic solvent (tetrahydrofuran or dioxane), when used to spin coat a polyvinylphenol dielectric layer over a TPDSi₂+TFB semiconductor layer, could be used for preparing OFET devices with comparable performance. When TFB alone was used as the semiconductor, deposition of the dielectric layer in tetrahydrofuran completely dissolved the TFB.

The invention may be embodied in other specific forms without departing from the spirit or essential characteristics thereof. The foregoing embodiments are therefore to be considered in all respects illustrative rather than limiting on the present teachings described herein. Scope of the invention is thus indicated by the appended claims rather than by the foregoing description, and all changes that come within the meaning and range of equivalency of the claims are intended to be embraced therein.

1. A thin film transistor device comprising a semiconducting composition adjacent to a dielectric component, wherein the semiconducting composition comprises a matrix product of a p-type semi conducting crosslinker and a p-type semiconducting polymer.

2. The thin film transistor device of claim 2, wherein the matrix product comprises the p-type semiconducting polymer embedded in a reaction product of the p-type semiconducting crosslinker.

3. The thin film transistor device of claim 1, wherein the p-type semiconducting crosslinker is a p-type π-conjugated compound.

4. The thin film transistor device of claim 1, wherein the p-type semiconducting crosslinker is a compound of Formula I or Formula II: 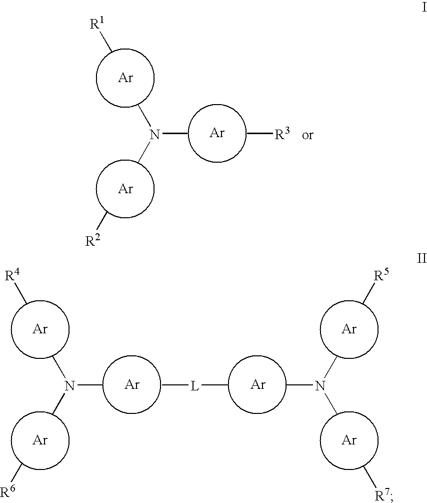
wherein:
R¹, R², R³, R⁴, R⁵, R⁶, and R⁷ independently are H or a C₁₋₁₀ alkyl group optionally substituted with 1-4 —SiR⁸R⁹R¹⁰;
Ar at each occurrence, is a C₆₋₁₄ aryl group or a 5-14 membered heteroaryl group, each of which optionally is substituted with 1-4 R¹¹;
R⁸, R⁹, and R¹⁰ independently are halogen, —N(C₁₋₁₀ alkyl)₂, —C(O)O(C₁₋₁₀ alkyl),
a C₁₋₁₀ alkyl group, or a C₁₋₁₀ alkoxy group;
R¹¹, at each occurrence, is halogen, —CN, —NO₂, —C(O)H, —C(O)OH, —CONH₂,
—OH, —NH₂, —CO(C₁₋₁₀ alkyl), —C(O)OC₁₋₁₀ alkyl, —CONH(C₁₋₁₀ alkyl), —CON(C₁₋₁₀ alkyl)₂, —OC₁₋₁₀ alkyl, —NH(C₁₋₁₀ alkyl), —N(C₁₋₁₀ alkyl)₂, a C₁₋₁₀ alkyl group, a C₂₋₁₀ alkenyl group, a C₂₋₁₀ alkynyl group, a C₁₋₁₀ haloalkyl group, a C₁₋₁₀ alkoxy group, a C₆₋₁₄ aryl group, a C₃₋₁₄ cycloalkyl group, a 3-14 membered cycloheteroalkyl group, or a 5-14 membered heteroaryl group; and
L is a divalent C₁₋₁₀ alkyl group, a divalent C₆₋₁₄ aryl group, a divalent 5-14 membered heteroaryl group, or a covalent bond.

5. The thin film transistor device of claim 4, wherein at least two of R¹, R², and R³ and at least two of R⁴, R⁵, R⁶, and R⁷ independently are a C₁₋₄ alkyl group substituted with —SiCl₃ or —Si(C₁₋₁₀ alkoxy)₃.

6. The thin film transistor device of claim 4, wherein Ar, at each occurrence, is a phenyl group, a thienyl group, a furanyl group, a pyrrolyl group, an indenyl group, a naphthyl group, a benzothienyl group, a benzofuranyl group, or an indolyl group, each of which optionally is substituted with 1-4—R¹¹.

7. The thin film transistor device of claim 4, wherein each Ar is a phenyl group.

8. The thin film transistor device of claim 4, wherein L is a divalent C₆₋₁₄ aryl group or a covalent bond.

9. The thin film transistor device of claim 1, wherein the p-type semiconducting crosslinker is N⁴,N^{4′}-diphenyl-N⁴,N^{4′}-bis(4-(((trichlorosilyl)propyl))phenyl)biphenyl-4,4′-diamine.

10. The thin film transistor device of claim 1, wherein the p-type semiconducting polymer is a p-type π-conjugated polymer.

11. The thin film transistor device of claim 1, wherein the p-type semiconducting polymer comprises a polythiophene, a polyfluorene, a polyarylsilole, a polycarbazole, or a polyarylamine.

12. The thin film transistor device of claim 1, wherein the p-type semiconducting polymer comprises poly[9,9-dioctyl-fluorene-co-N-butylphenyl)-diphenylamine].

13. The thin film transistor device of claim 1, wherein the dielectric component is selected from an oxide dielectric component and an organic dielectric component.

14. (canceled)

15. The thin film transistor device of claim 13, wherein the organic dielectric component comprises a polymeric dielectric or a molecular dielectric.

16. The thin film transistor device of claim 15, wherein the molecular dielectric is a self-assembled nanodielectric.

17. The thin film transistor device of claim 15, wherein the polymeric dielectric is a thermally or photochemically curable polymer or polymer blend.

18. The thin film transistor device of claim 1, further comprising a substrate coupled with, adjacent to, or removed from the semiconducting composition, wherein the substrate is selected from a glass, a silicon, an indium oxide material, and a polymeric material.

19. A method of fabricating the thin film transistor device of claim 1.

20. (canceled)

21. (canceled)

22. (canceled)

23. (canceled)

24. A complementary circuit comprising the thin film transistor device of claim 1.

25. An electronic device comprising the complementary circuit of claim 24.
